(19) United States
(12) Patent Application Publication
(10) Pub. No.: US 2023/0152076 A1
(43) Pub. Date: May 18, 2023

(54) SYSTEM AND METHOD FOR EMF MANIPULATION

(71) Applicant: Manus Technology Group B.V., Geldrop (NL)

(72) Inventors: Paul VERCOELEN, Geldrop (NL); Pim OSTENDORF, Geldrop (NL)

(21) Appl. No.: 18/056,378

(22) Filed: Nov. 17, 2022

Related U.S. Application Data
(60) Provisional application No. 63/280,900, filed on Nov. 18, 2021.

(51) Int. Cl. G01B 7/004; G06F 3/01; G06F 3/0346

(52) U.S. Cl. CPC G01B 7/004; G06F 3/014; G06F 3/0346

(57) ABSTRACT

A system and method for shaped wave patterning for EMF tracking. The waves are shaped at the source, when generating the input signal. The waves may be shaped as square patterns or triangular patterns.

### FIELD OF THE INVENTION

The present invention relates to a system and method for EMF (electromagnetic field) manipulation and in particular, to such a system and method for shaped wave patterning for EMF tracking.

### BACKGROUND OF THE INVENTION

EMF (electromagnetic field) sensors may be used for detecting the position of any attached object and hence may be used for tracking. For example, such sensors may be used to detect the position of humans and/or specific human appendages when attached to a human, for example when worn as an item of clothing. Determining the position of humans and/or specific human appendages may be useful, for example, for virtual reality (VR) or augmented reality (AR) devices.

US Published Application No. 20170090568 to Ke-Yu Chen et al describes such an item of clothing, which is a glove that features multiple magnetic field generators at various locations on the glove, for example at the fingertips, and a single magnetic flux density sensor or magnetic field strength sensor at a predetermined position relative to the glove, for example at the wrist. As described, each magnetic field generator includes one or more electromagnets that can be independently driven to result in the creation of a three dimensional magnetic field with known wave-like characteristics and geometry. Furthermore, the magnetic fields generated by each of the electromagnets can be distinguished from magnetic fields generated by other electromagnets by controlling one or more of the wave-like characteristics of the field. For example, each electromagnet can be driven at a different frequency (e.g., frequency division multiplexing) for disambiguation from other electromagnets. Alternatively, each electromagnet can be driven at a different instance in time (e.g., time division multiplexing) for disambiguation from (and interoperability with) other electromagnets or undesired interference in the form of ambient or external magnetic flux. However, this application requires centralized control and synchronization of the signals to avoid interference.

### BRIEF SUMMARY OF THE INVENTION

The present invention overcomes the drawbacks of the background art, by providing a system and method for shaped wave patterning for EMF tracking. The waves are shaped at the source, when generating the input signal. The waves may be shaped as square patterns or triangular patterns.

Implementation of the method and system of the present invention involves performing or completing certain selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

Unless otherwise defined, all technical and scientific terms used herein have the same meaning as commonly understood by one of ordinary skill in the art to which this invention belongs. The materials, methods, and examples provided herein are illustrative only and not intended to be limiting.

An algorithm as described herein may refer to any series of functions, steps, one or more methods or one or more processes, for example for performing data analysis.

Implementation of the apparatuses, devices, methods and systems of the present disclosure involve performing or completing certain selected tasks or steps manually, automatically, or a combination thereof. Specifically, several selected steps can be implemented by hardware or by software on an operating system, of a firmware, and/or a combination thereof. For example, as hardware, selected steps of at least some embodiments of the disclosure can be implemented as a chip or circuit (e.g., ASIC). As software, selected steps of at least some embodiments of the disclosure can be implemented as a number of software instructions being executed by a computer (e.g., a processor of the computer) using an operating system. In any case, selected steps of methods of at least some embodiments of the disclosure can be described as being performed by a processor, such as a computing platform for executing a plurality of instructions. The processor is configured to execute a predefined set of operations in response to receiving a corresponding instruction selected from a predefined native instruction set of codes.

Software (e.g., an application, computer instructions) which is configured to perform (or cause to be performed) certain functionality may also be referred to as a “module” for performing that functionality, and also may be referred to a “processor” for performing such functionality. Thus, processor, according to some embodiments, may be a hardware component, or, according to some embodiments, a software component.

Further to this end, in some embodiments: a processor may also be referred to as a module; in some embodiments, a processor may comprise one or more modules; in some embodiments, a module may comprise computer instructions—which can be a set of instructions, an application, software—which are operable on a computational device (e.g., a processor) to cause the computational device to conduct and/or achieve one or more specific functionality.

Some embodiments are described with regard to a “computer,” a “computer network,” and/or a “computer operational on a computer network.” It is noted that any device featuring a processor (which may be referred to as “data processor”; “pre-processor” may also be referred to as “processor”) and the ability to execute one or more instructions may be described as a computer, a computational device, and a processor (e.g., see above), including but not limited to a personal computer (PC), a server, a cellular telephone, an IP telephone, a smart phone, a PDA (personal digital assistant), a thin client, a mobile communication device, a smart watch, head mounted display or other wearable that is able to communicate externally, a virtual or cloud based processor, a pager, and/or a similar device. Two or more of such devices in communication with each other may be a “computer network.”

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the drawings:

FIG. 1A shows a non-limiting, exemplary system for shaped wave patterning;

FIGS. 1B and 1C show non-limiting, illustrative examples of various wave shapes;

FIG. 1D shows another non-limiting, exemplary system for shaped wave patterning;

FIG. 2 shows an exemplary, non-limiting method for operating a system according to FIG. 1A or 1D;

FIG. 3 shows a non-limiting, exemplary schematic of a glove that is to be worn by a user, for tracking the positions of the fingers;

FIG. 4 is a non-limiting, exemplary schematic diagram of the electronics and sensors used in the glove of FIG. 3;

FIG. 5 shows an exemplary, non-limiting method for gauging RF (radiofrequency) interference) with a plurality of EMF sensors;

FIG. 6 shows an exemplary, non-limiting system incorporating a plurality of wearable devices as described herein;

FIG. 7 shows an exemplary, non-limiting method for operating a system incorporating a plurality of wearable devices as described herein;

FIG. 8 shows an exemplary, non-limiting method for operating a system according to FIG. 1A or 1D, and FIG. 6; and

FIGS. 9A and 9B relate to non-limiting, exemplary methods for transmission of binary data through EMF transmission.

### DESCRIPTION OF AT LEAST SOME EMBODIMENTS

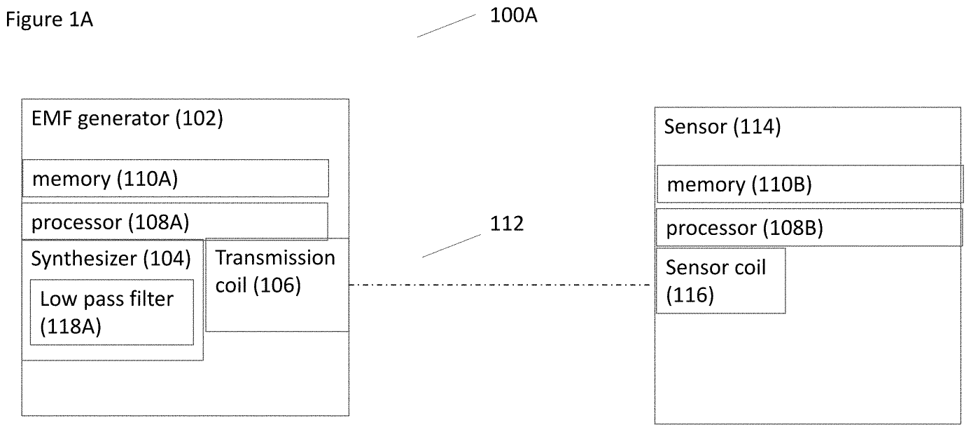

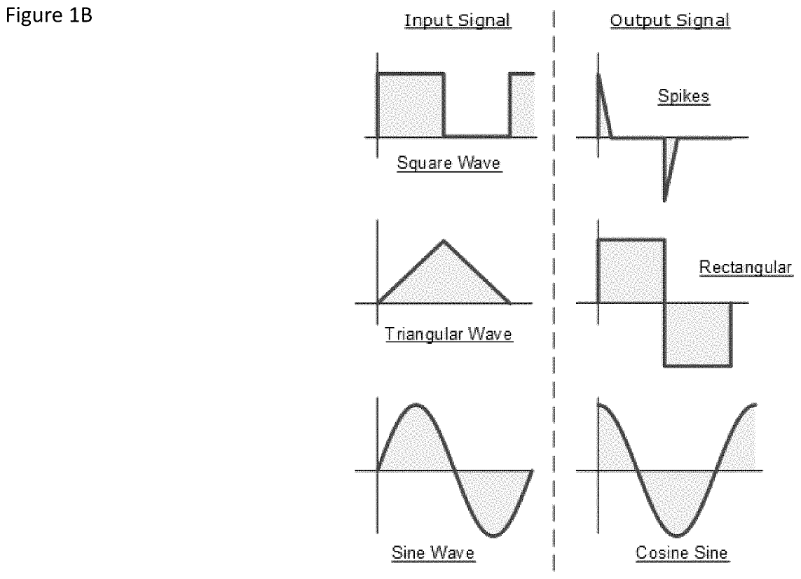

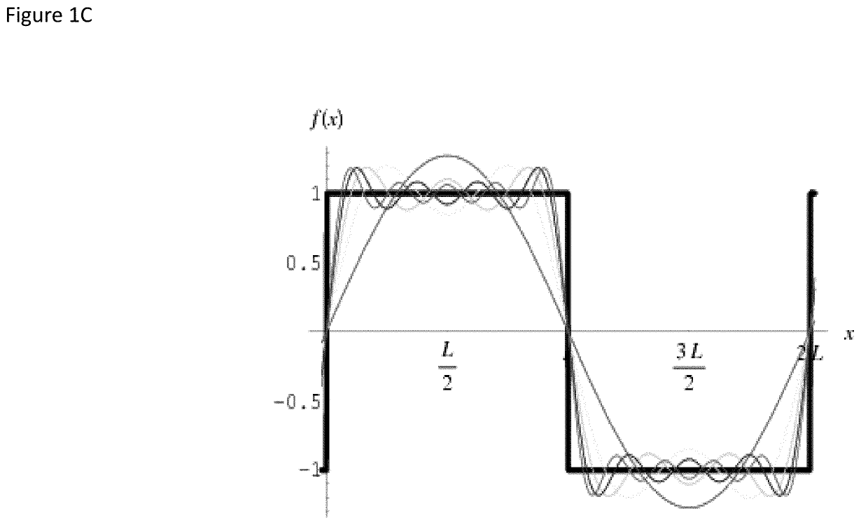

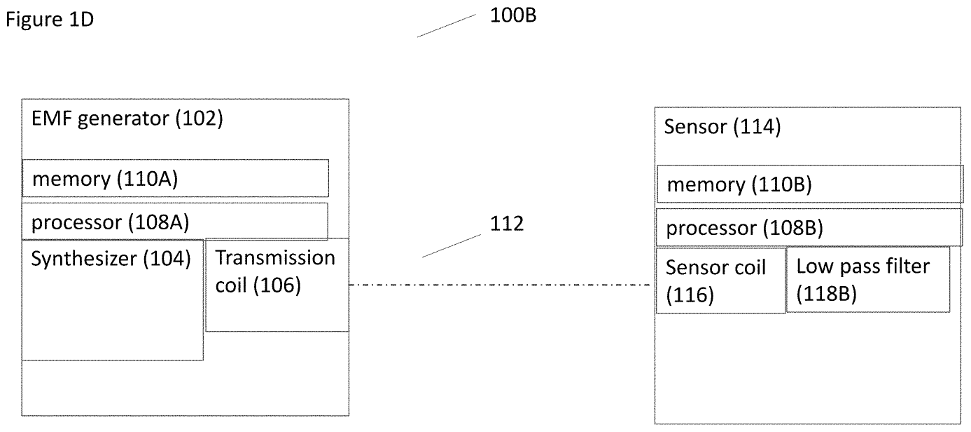

FIG. 1A shows a non-limiting, exemplary system for shaped wave patterning. As shown in a system 100A, an EMF generator 102 comprises a synthesizer 104 and a transmission coil 106. Synthesizer 104 generates the electrical signals which are then passed to transmission coil 106 for transmission as EMF signals 112. A processor 108A executes instructions stored in a memory 110A to determine when EMF signals 112 are to be emitted by transmission coil 106. Such signals 112 are emitted intermittently, with a periodicity and duration of transmission that is determined according to the instructions stored in the memory 110A and executed by the processor 108A. In particular, the shape of the waves is determined according to these instructions, which in turn determine the electrical signals that are put into transmission coil 106.

EMF signals 112 are received by a sensor 114, through a sensor coil 116. A processor 108B executes instructions stored in a memory 110B which enables the received signals from sensor coil 116 to be measured and optionally for further processing on these signals to be performed.

EMF signals 112 pass through sensor coil 116 and in turn induce a current in sensor coil 116 based on the rate of change of this magnetic field. The current and therefore also the voltage over sensor coil 116 takes the shape of the first derivative of the electrical signal that is put into transmission coil 106. The optimal shape of the input electrical signals from synthesizer 104 may be determined so that EMF signals 112 may remain measurable as far away as possible. The optimal shape may comprise a square wave or a triangular wave. Instructions stored in memory 110A and executed by processor 108A determine the shape of the input electrical signals.

Although the optimal shape of the electrical signals may comprise a square wave, because such a shape may provide the largest measurable range for sensor 114, the derivative of a square wave is a pulse on the rising edge and another one on the falling edge of each square. These pulses are extremely short and thus difficult to measure at sensor 114. Shaping the electrical input signals as triangular signals makes EMF signals 112 easier to measure at sensor 114, because the derivative is a square wave. In addition, such a triangular shape enables binary information to be embedded in the transferred signal. FIG. 1B shows non-limiting, illustrative examples of various wave shapes according to the input signal and the resultant output signal at sensor 114.

When shaping the electrical input signals as triangular signals, the steepness of the signal increases with the frequency of the signal. As the frequency of the input signals increases, the measurable range of EMF signals 112 for sensor 114 also increases. In addition, such a triangular wave results in a square wave when measured by sensor 114, such that binary data may easily be embedded in this signal. Differentiating between signals from different EMF generators 102 and/or from a single EMF generator 102 but generated at different times, is easier. Optionally a start and end code may be embedded in EMF signals 112 for synchronization. Such differentiation may also enable a plurality of different sensors 114 to measure each other's signal and so to determine the distance between them.

FIG. 1C illustrates a plurality of signals in a square wave shape, showing how a square wave may be measured at sensor 114. Such a square wave is preferably processed at sensor 114 with a very short pulse. Sensor 114 therefore needs to measure EMF signals 112 at the exact time of the pulse if a square wave is implemented. Such EMF signals 112 may be measured by employing a Fourier series and providing such signals at a plurality of different frequencies. For such an implementation, synthesizer 104 preferably comprises an analog low pass filter 118A, to remove all high frequencies from the generated electrical signals and to therefore obtain the base frequency. The base frequency may then be used for further calculations. Such an implementation optimizes the signal for the magnetic field, and for amplitude and phase detection, without wishing to be limited by a closed list.

FIG. 1D shows a similar system as for FIG. 1A, except that low pass filter 118B is now located at sensor 114. That is, low pass filter 118B is now located at the EMF receiver rather than the EMF transmitter. The other components in system 100B operate in an identical or at least similar manner to the components of system 100A.

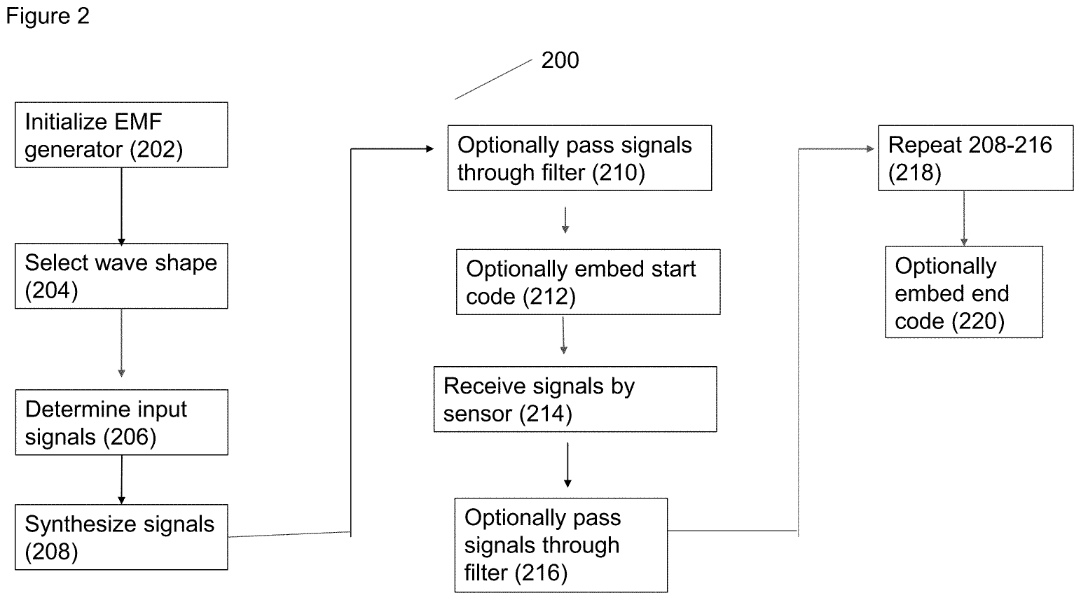

FIG. 2 shows an exemplary, non-limiting method for operating a system according to FIG. 1A. As shown in a method 200, the process begins at 202 with initialization of the EMF generator. At 204, a wave shape is selected according to instructions executed by the processor at the EMF generator. The wave shape may be triangular or square shaped, as described with regard to FIG. 1, depending for example on the configuration of the EMF generator.

At 206, instructions executed by the processor determine the input electrical signals to the transmission coil, which in turn determine the wave shape. These input electrical signals are then generated by a synthesizer according to the executed instructions at 208. If a square wave is to be transmitted by the transmission coil, then optionally the signals are passed through an analog low pass filter at 210.

However, if a triangular wave shape is to be transmitted, then at 212 optionally a start code is embedded in the transmitted EMF signals, to indicate the start of EMF signal transmission and/or a particular period of EMF signal transmission. At 214, EMF signals are received by the sensor. Various measurements and/or other types of processing may then be performed as described herein. If a square wave is to be received by the sensor, but an analog low pass filter has not been applied at the transmission coil, then optionally the signals are passed through an analog low pass filter at 216.

At 218, stages 208-216 may be repeated. At 220, if a triangular wave shape is being transmitted, optionally an end code is embedded in the transmitted EMF signals, to indicate the end of EMF signal transmission and/or a particular period of EMF signal transmission.

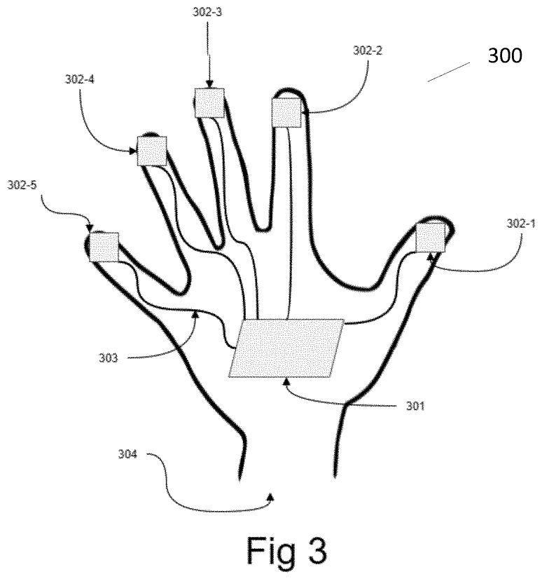

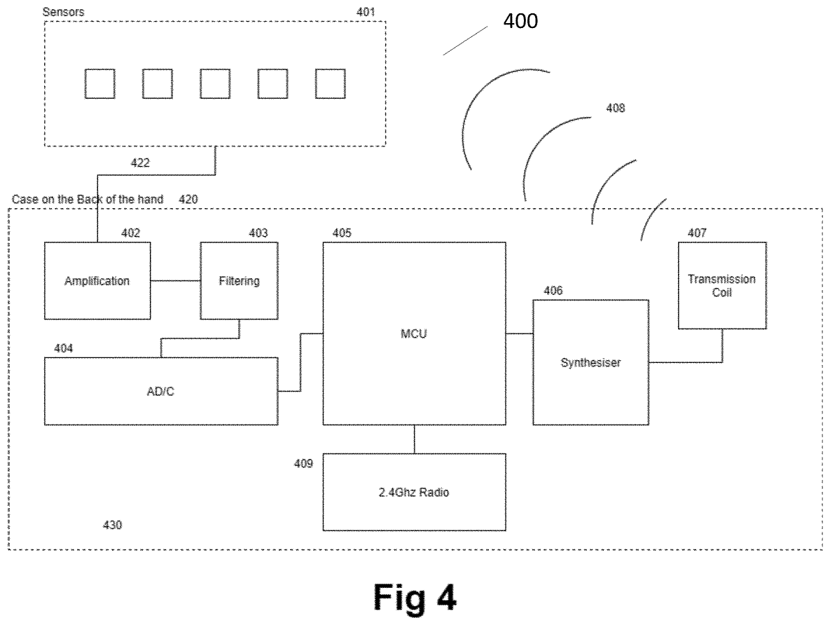

FIGS. 3 and 4 relate to exemplary, illustrative implementations of shaped wave patterning for tracking human appendages with magnetic fields. Without wishing to be limited in any way, the present invention may be used to track the position of arms, legs, head, torso, hands, feet joints and/or individual fingers. Sensors for such magnetic fields are attached to each such appendage that is to be separately tracked. For example, the sensors may be attached to an item of clothing that is worn by the user on the appropriate appendage. It is desirable to be able to track such appendages for more than one user at the same or similar time. For example, two or more users may have such sensors attached to items of clothing, and may then come into physical proximity. Differentiating between the systems that are attached to the different users is important for correct tracking of each such appendage.

FIG. 3 shows a non-limiting, exemplary schematic of a glove that is to be worn by a user, for tracking the positions of the fingers. A glove 300 is worn on a hand 304 of the user. Glove 300 may feature a single EMF source 301, which may be placed at the palm or wrist of glove 300 as shown. A plurality of fingers is tracked with a plurality of sensors 302, for sensing the EMF generated by EMF source 301. EMF source 301 may generate triangular shaped waves, square shaped waves or a combination thereof. If square shaped waves are at least generated primarily, EMF source 301 may feature a lower power implementation than if sinusoidal waves are generated. Alternatively, sensors 302 may be correspondingly less sensitive.

In this non-limiting implementation, each finger of glove 300 features a sensor 302, shown as a sensor 302-1 on the thumb, and as sensors 302-2 to 302-5 on the other fingers. A plurality of wires 303 optionally connect sensors 302 to EMF source 301, to connect analog signals from sensors 302 to EMF source 301. Alternatively, a wireless communication unit may provide a data communication channel from sensors 302 to EMF source 301. Such a wireless communication unit is preferably implemented with triangular shaped waves, due to the lower power requirements. As described below in greater detail, EMF source 301 also comprises a processor and memory for storing instructions, for analyzing the incoming signals from sensors 302.

Glove 300 may comprise any suitable fabric or material for placing each sensor 302 in a desired position on a finger or thumb of the user. For example and without limitation, each sensor 302 may be placed closer to a tip of the finger or thumb of the user as shown. Glove 300 may comprise continuous fabric or material, or may have such fabric or material at a plurality of locations, but not necessarily covering the entire hand. For example, fabric may encircle a location on each finger or thumb where sensor 302 is to be placed, and may further comprise straps or other connecting material between sensors 302 and source 301. A wristband or other material may support source 301 in a desired location, such as on or near the palm or wrist of the user, or on the back of the hand of the user. Source 301 may be contained within a case (not shown; see FIG. 2).

Sensors 302 may comprise a magnetic flux density sensor or magnetic field strength sensor, three Hall effect sensors or any other suitable magnetic sensor or combination thereof. It should be noted that for the combined application of such sensors to sample a set frequency to gauge RF interference, as well as for EMF signal reception, Hall effect sensors are not used. Such sensors preferably operate at a frequency of at least six times the sample frequency, more preferably at least eight times and most preferably at least 10 times. Each such sensor may comprise a magnetometer which is able to detect EMF from source 301, but preferably comprises a sensor that is at least able to determine an amplitude of the EMF at the appropriate speeds.

As shown, preferably the location of each finger is tracked with a separate sensor 302, while the location of all sensors 302, and hence all fingers on one hand, is preferably tracked with one EMF source 301. However, different gloves 300 may each use a separate source 301 to track their corresponding sensors 302 and hence their corresponding fingers. For example, if EMF source 301 emits triangular shaped waves, then a start code and end code may be embedded, such that sensors 302 for each glove 300 is more easily able to determine which EMF signals are relevant. Each such EMF source 301 creates an alternating magnetic field, which is preferably emitted periodically for a short period of time. The duration of this period of time is preferably determined according to the frequency of the sine wave that is sent out.

FIG. 4 is a non-limiting, exemplary schematic diagram of the electronics and sensors used in the glove of FIG. 3. As shown, a system 400 comprises a plurality of sensors 401, which are preferably located at the fingers and thumb of the user as previously described with regard to FIG. 3. Sensors 401 may comprise the types of sensors described with regard to FIG. 3, for example. A case 420 may be attached to the wrist or hand of the user, for example at the palm or back of the hand. Case 420 contains a plurality of components as shown, including without limitation a transmission coil 407 which emits EMF 408 as shown, for detection by sensors 401.

An amplification unit 402 receives signals from sensors 401 through a plurality of wires 422, of which one is shown for simplification. Amplification unit 402 then amplifies the received signal and passes the amplified signal to a filtering unit 403. Filtering unit 403 may comprise one or more cut-off filters and/or notch filters, to reduce noise and to boost the desired signal frequency, optionally comprising and/or in addition to the low pass filter if necessary. The signal is then passed to an ADC (analog-to-digital converter) 404, to digitize the analog signals for further processing. The digitized signals may then by analyzed by a MCU (microcontroller unit) 405, which comprises a processor unit, a memory, communication interfaces and peripherals (not shown).

MCU 405 also determines when EMF signals 408 are to be emitted by transmission coil 407, as well as the required shape as described herein. Such signals 408 are emitted intermittently, with a periodicity and duration of transmission that is determined according to instructions stored in the memory and executed by the processor. The signals are generated by a synthesizer 406 and then passed to transmitter 407.

Analyzed data may be transmitted by a radio 409, which in this non-limiting example comprises a 2.4 GHz radio.

To determine when EMF signals 408 are to be emitted, MCU 405 features a clock (not shown) for timing this activity and other activities. Such clocks typically have an expected accuracy, which determines the precision of the timing. The clock may for example comprise an internal oscillator, such as an internal RC oscillator, featuring a linear oscillator circuit which uses an RC network, a combination of resistors and capacitors. Alternatively, the clock may preferably comprise a crystal clock. The precision of the clock may be defined in terms of tolerance, which is the extent (by time) to which the clock signal timing differs from the expected timing. The greater the tolerance, the lower the precision of the clock and hence the greater possible variability in timings between different clocks, such as those located at different gloves. This variability in turn means that EMF signals 408 will be emitted at different times for MCUs 405 located on different gloves.

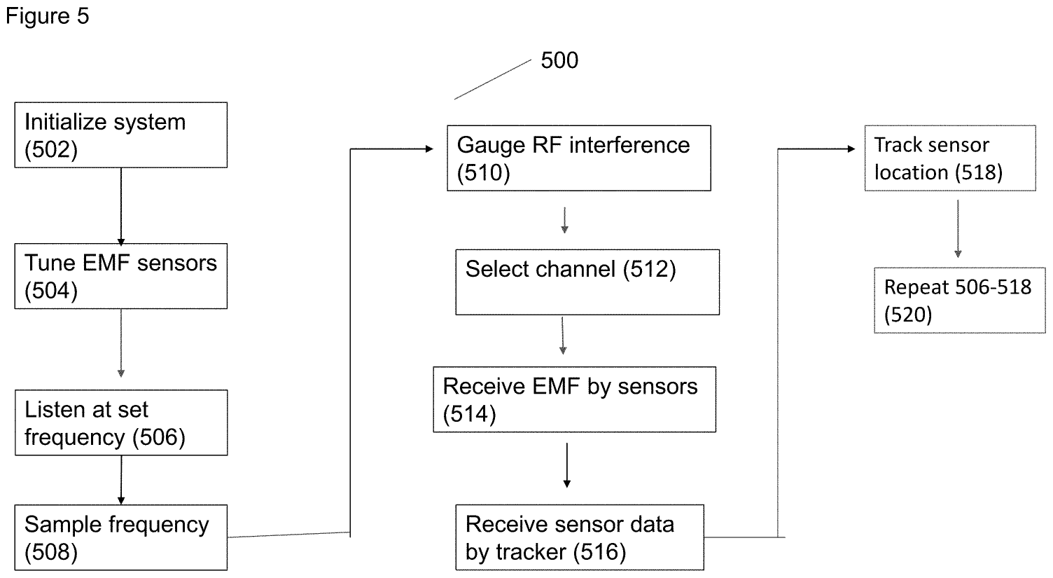

FIG. 5 shows an exemplary, non-limiting method for gauging RF (radiofrequency) interference) with a plurality of EMF sensors. The EMF sensors when tuned properly can also act as an antenna. When not used for EMF tracking, they can be used to sample the 2.4 Ghz radio band and use this to determine the optimal channel to send its data over. Any suitable sensor may be used for this implementation, with the exception of Hall effect sensors. A non-limiting implementation of a sensor system featuring a generated 2.4 Ghz radio band is shown with regard to FIG. 4. Without wishing to be limited by a closed list, such an optimal channel selection improves both the range of the sensor system and power draw.

A method 500 starts at 502, when the system is initialized. Such initialization may include initiating the functions of the EMF generator and of the sensors as described herein. At 504, the sensor coil for the EMF sensors is adjusted so that it is able to act as an antenna for a set frequency. The adjustment comprises adjusting the sensor coil and its tuning, such that the output of the sensor coil would be switched to a different circuit, for example through a MUX, when receiving the set frequency. Also optionally, alternatively or additionally, a portion of the sensor coil would be of the correct size and shape to receive the set frequency. The set frequency may for example comprise the 2.4 Ghz radio band, but in any case, is different from the frequency used for EMF tracking.

At 506, the sensors listen at this set frequency. Such listening preferably occurs according to instructions executed by a processor at each sensor, such that the sensor alternates between listening for the set frequency and listening for EMF signals used for EMF tracking. At 508, each sensor samples the set frequency. At 510, such samples are analyzed by the sensor to gauge RF interference, by measuring the incoming energy on each potential channel. The incoming energy may be used to determine potential RF interference, such that preferably a channel is selected that is less heavily used. According to such a preference, a channel is selected by the sensor at 512. Now EMF signals are received by the sensors at the selected channel at 514. The sensor data then received by a tracker at 516, such that EMF tracking may be performed. At 518, the sensor location is determined according to the sensor data. At 520, optionally stages 506-518 are repeated at least once.

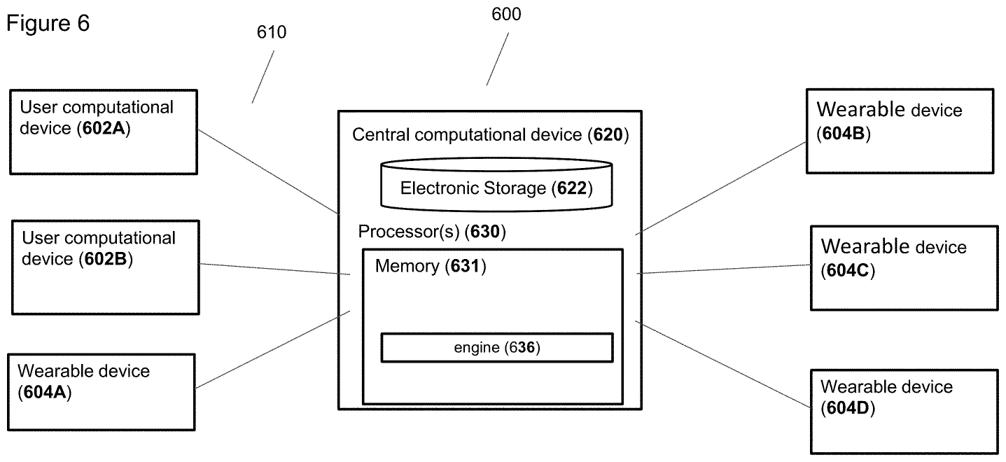

FIG. 6 shows an exemplary, non-limiting system incorporating a plurality of wearable devices as described herein. As shown, a system 600 features a plurality of wearable devices 604, of which four are shown herein as wearable devices 604A-604D for the purpose of illustration and without any intention of being limiting. Wearable devices 604 may comprise devices as described herein, such as the gloves described herein and/or a headset. System 600 also optionally and preferably features a central computational device 620, which is in contact with wearable devices 604 through a computer network 610. Network 610 may comprise any suitable wired or wireless communication network, including without limitation Wi-Fi, Bluetooth, radio frequencies and cellular network communication.

Central computational device 620 preferably comprises a processor 630 and a memory 631. Memory 631 stores a plurality of instructions for execution by processor 630 to fulfill the functions of central computational device 620, for example and without limitation to provide an engine 636. For example and without limitation, engine 636 may support game play for an interactive electronic game. A plurality of users may wear wearable devices 604, and may interact with the game according to game play supported by engine 636. The relative location of the users may be determined through wearable devices 604; such a relative location may affect game play. The location may be provided to central computational device 620 by wearable devices 604. In turn, central computational device 620 may send information and/or instructions, and/or may fulfill such functions as keeping score, according to the provided location.

Central computational device 620 may also comprise an electronic storage 522, for example for storing user profile information, additional game data and/or other information for supporting the functions of central computational device 620 and/or of system 600 overall.

System 600 may also, additionally or alternatively, comprise a plurality of user computational devices 602, shown as user computational devices 602A and 602B for the purpose of illustration only and without any intention of being limiting. Optionally one or more user computational device(s) 602 replace central computational device 620. User computational devices 602A and 602B may be used for example to control game play, to receive information about game play and/or to participate in game play, in combination with wearable devices 604. Other optional uses include but are not limited to motion capture (for example for film and/or animation), education, training, coaching (for example for sports or other activities), simulation and so forth.

Within system 600, synchronization between wearable devices 604 may occur according to instructions from central computational device 620, one or more user computational devices 602A and 602B, and/or in a peer to peer manner. If triangular shaped waves are transmitted by an EMF source, then synchronization may occur according to start and end codes. Optionally a single EMF source, or fewer EMF sources, may be implemented in system 600 due to such synchronization (not shown). Additionally or alternatively, triangular shaped waves may enable the distance between an EMF source and one or more sensors to be larger, the power of the EMF source to be lower and/or the sensors to be less sensitive. Such adjustments may decrease the cost, or otherwise increase the ease and simplicity of implementation of wearable devices 604.

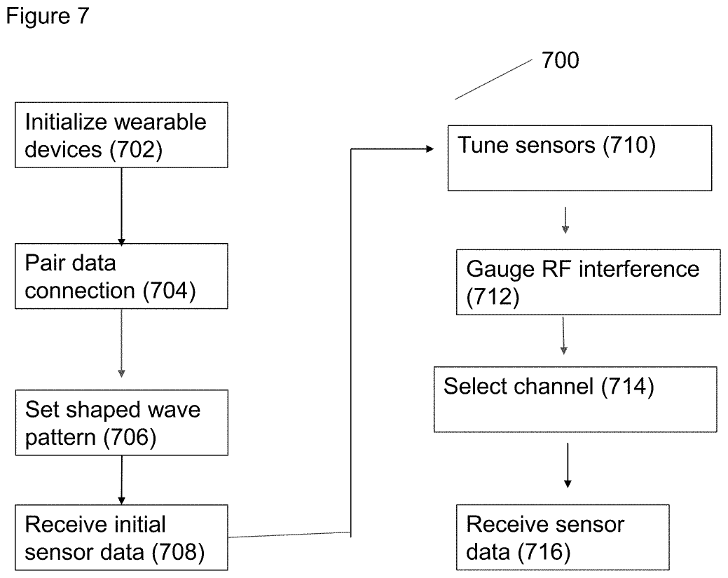

FIG. 7 shows an exemplary, non-limiting method for operating a system incorporating a plurality of wearable devices as described herein. As shown in a method 700, the process begins by initializing a plurality of wearable devices at 702. The wearable devices are assumed to comprise at least one, and preferably a plurality of, sensors. For example, for a wearable device comprising a glove, each of a plurality of fingers features a sensor, while the glove may feature a single EMF source, for example at the wrist, back of the hand or palm of the hand. Optionally a plurality of gloves may share a single EMF source as described herein, in which case the EMF source may be remote from the glove. If square shaped waves are used, optionally a single EMF source may transmit to a single glove, but may still be remote from the glove.

Such initialization may include calibration, for example. Initialization may also include functions to support initial communication between the plurality of sensors and the EMF source. The user may put on (wear) the wearable device during the initialization process or before it begins. Pairing may then occur with a data connection for each wearable device at 704. The data connection may for example feature a connection to the previously described EMF generator, which may control EMF source, and/or to a central computational device as previously described.

At 706, the wave shaped pattern is selected, preferably as square shaped waves, triangular shaped waves or a combination thereof; in which the combination is preferably implemented as a rapid sequence of alternating wave shapes, optionally in a pattern with a plurality of repeated waves of a particular shape. Optionally the wave shapes may be combined to create a distorted wave shape. At 710, the sensors are tuned, for example as previously described. At 712, the degree of RF interference is determined, for example as previously described. At 714, the channel for receiving EMF signals by each sensor is selected according to the degree of RF interference, for example as previously described. At 716, sensor data is received.

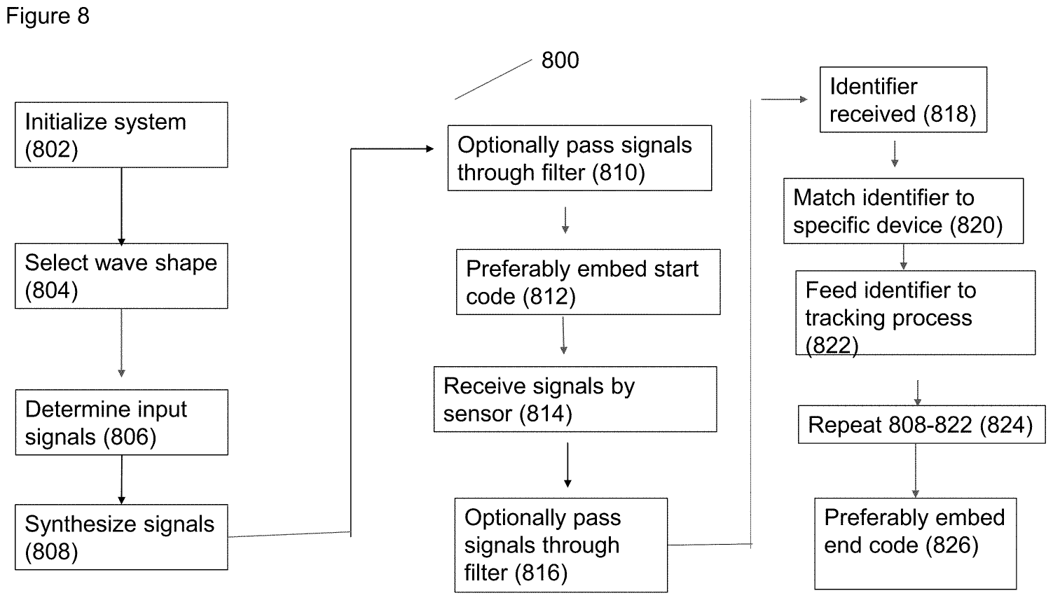

FIG. 8 shows an exemplary, non-limiting method for operating a system according to FIG. 1A or 1D, and FIG. 6. The system is assumed to feature a plurality of wearable devices, although any potentially mobile device may be substituted for one or more wearable devices. Each wearable device preferably features the components of FIG. 1A or 1D, although these components may be distributed across multiple locations, such that for example an EMF source may be located at one location and the corresponding sensor at a different location. The wearable devices may perform peer-to-peer tracking, to determine a relative location of one or more other wearable devices to each wearable device; tracking may be performed centrally; or a combination thereof.

In a method 800, the method begins at 802 by initializing the system, including initializing each wearable device and any central device that receives information from one or more wearable devices. Initialization may be performed as described herein for the EMF source and sensor.

At 804, a wave shape is selected according to instructions executed by the processor at the EMF generator. The wave shape may be triangular or square shaped, as described with regard to FIG. 1, depending for example on the configuration of the EMF generator. However, for an embedded identifier to be sent, preferably the wave shape is triangular for at least the time period during such the identifier is transmitted.

At 806, instructions executed by the processor determine the input electrical signals to the transmission coil, which in turn determine the wave shape. These input electrical signals are then generated by a synthesizer according to the executed instructions at 808. If a square wave is to be transmitted by the transmission coil, then optionally the signals are passed through an analog low pass filter at 810.

However, if a triangular wave shape is to be transmitted, then at 812 preferably a start code is embedded in the transmitted EMF signals, to indicate the start of EMF signal transmission and/or a particular period of EMF signal transmission. The start code preferably comprises an identifier, to identify the transmitting EMF source, which is preferably a wearable device as described herein. At 814, EMF signals are received by the sensor. Various measurements and/or other types of processing may then be performed as described herein. If a square wave is to be received by the sensor, but an analog low pass filter has not been applied at the transmission coil, then optionally the signals are passed through an analog low pass filter at 816.

When a triangular wave shape has been transmitted, with the identifier, then a receiving device determines that an identifier has been transmitted at 818. At 820, the receiving device may match the identifier to a particular wearable device. For example, if the receiving device is another wearable device, then the receiving device may identify a specific wearable device as being within receiving range, for example for tracking purposes. Additionally or alternatively, such information may be determined by a central receiving device.

At 822, the identification is fed into a tracking process for determining at least the relative location of at least two wearable devices, relative to each other.

At 824, stages 808-822 may be repeated. At 826, if a triangular wave shape is being transmitted, preferably an end code is embedded in the transmitted EMF signals, to indicate the end of EMF signal transmission and/or a particular period of EMF signal transmission.

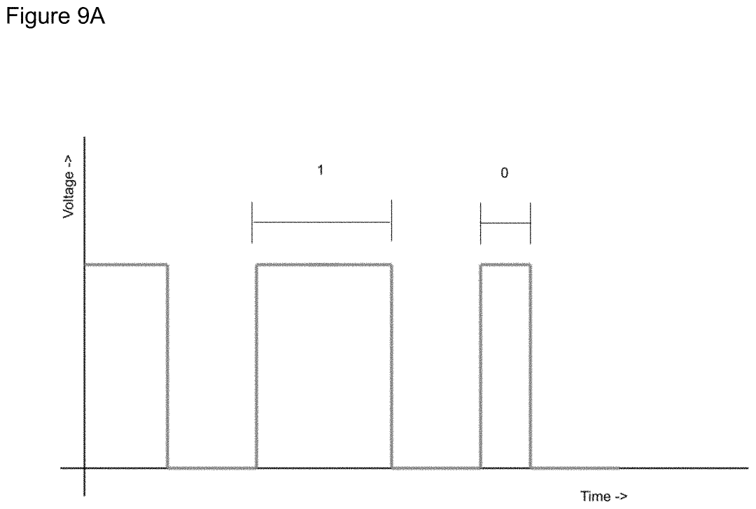

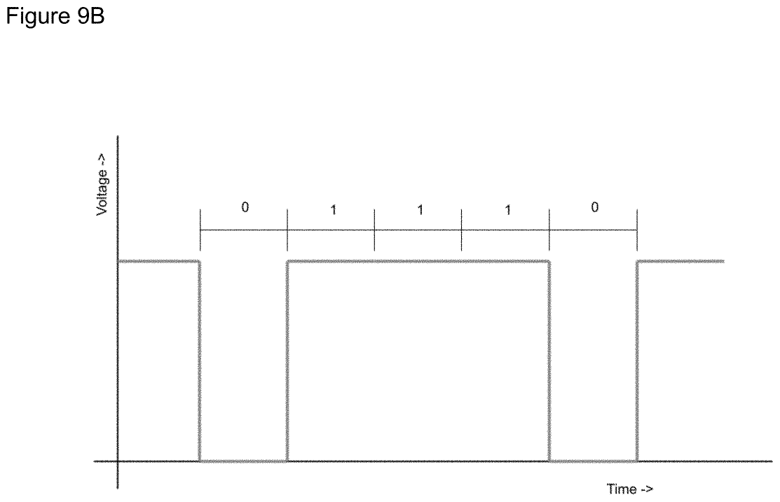

FIGS. 9A and 9B relate to non-limiting, exemplary methods for transmission of binary data through EMF transmission. The systems and methods as described herein may be used for transmission of binary data, and not only start/end codes and/or identity information. For example, the method of FIG. 8 may be used to send binary data more generally, whether to wearable devices and/or mobile devices, or for other purposes. These methods assume that a triangular wave is used as the transmission shape when creating the EM field (EMF), as in this situation, the derivative thereof is a square wave when received on another coil, for example at a sensor as described herein. By using either frequency modulation or timed pulsing of the EMF, binary data may be transmitted over the EM field to the receiver.

When using frequency modulation, the transmission processor varies the frequency of the transmitted EMF wave. The variation in frequency enables a 0 or a 1 to be encoded in the field, depending on the time the derived square signal is high vs low, as shown with regard to FIG. 9A. For example, when the derived square signal is high for longer than a threshold period of time, the field may be read as “1”; when the derived square signal is high for shorter than the threshold period of time, the field may be read as “0”, as shown in the diagram.

Another method, shown with regard to FIG. 9B, maintains a steady frequency but selectively maintains the voltage at a high or low level in a timed pulse. A high voltage level timed pulse is read as “1”; a low level timed pulse is read as “0”.

These methods may increase the difficulty of accurately deriving the receiver's position and rotation at the same time. One method to overcome this difficulty is to avoid using FFT (Fast Fourier Transform) to determine the core frequency but this avoidance increases overhead in the signal processor. Another method to overcome this difficult is to attach the data either on the start or end of the transmission signal, for example with regard to the start or end codes as described above. This way the processor can later determine what to do with the data it gathered.

The frequency of information transmission then determines the amount of data that may be transmitted in a particular period of time. For example, if data transmission occurs on a higher frequency and includes the actual transmission frequency used for the positioning calculations, the receiver and the transmitter do not require an alternative data stream to communicate basic settings. This short information field can then be used to transmit either source identification information, relative positioning in a wider space, and other information that might be relevant to the receiver.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A system for EMF tracking, comprising a transmission source for generating EMF waves having shaped wave patterning and a sensor for receiving said EMF waves, wherein said transmission source is tracked relative to said sensor according to said shaped wave patterning.

2. The system of claim 1, wherein said transmission source comprises a transmission coil and a synthesizer for generating an input signal for said transmission coil, wherein said shaped wave patterning is determined according to said input signal.

3. The system of claim 2, wherein said shaped wave patterning comprises a square pattern, a triangular pattern or a manipulated combination thereof.

4. The system of claim 3, wherein said synthesizer further comprises an analog low pass filter for generating said square pattern.

5. The system of claim 3, wherein said sensor further comprises an analog low pass filter for receiving said square pattern.

6. The system of claim 3, wherein said shaped wave patterning comprises a triangular pattern and wherein said synthesizer embeds a start code at a start of broadcasting said EMF waves.

7. The system of claim 6, wherein said synthesizer embeds an end code at an end of broadcasting said EMF waves.

8. The system of claim 7, wherein said synthesizer embeds an identifier in said EMF waves.

9. The system of claim 8, further comprising a receiver for receiving said identifier and for tracking said transmission source correspondingly.

10. The system of claim 2, wherein a location of said sensor is determined according to said shaped wave patterning.

11. The system of claim 1, wherein said shaped wave patterning comprises a triangular pattern and wherein said synthesizer embeds binary data according to frequency modulation or timed pulsing of the EMF.

12. The system of claim 1, wherein said sensor comprises a magnetic flux density sensor, a magnetic field strength sensor, three Hall effect sensors or any other suitable magnetic sensor or a combination thereof.

13. The system of claim 1, wherein said sensor comprises a sensor coil and a plurality of circuits, wherein said sensor coil is capable of receiving said EMF waves and waves of a set frequency that differs from a frequency of said EMF waves; wherein an output of said sensor coil is switched to a different circuit for receiving said waves of said set frequency; wherein said sensor samples said set frequency to determine incoming energy on each potential channel; wherein said sensor selects a channel with lower incoming energy for receiving said EMF signals.

14. The system of claim 13, wherein said sensor comprises a magnetic flux density sensor, a magnetic field strength sensor, or any other suitable magnetic sensor or a combination thereof.

15. The system of claim 1, wherein said sensor is attached to an appendage of a user, directly or worn on an item of clothing, and wherein said determination of said location is applied to track a position of said appendage; wherein said appendage is selected from the group consisting of an arm, a leg, a head, a torso, a hand, a foot, a joint, and an individual finger.

16. The system of claim 15, wherein an analysis of said waves is applied to differentiate between a plurality of such sensors worn by a plurality of users, by one user or a combination thereof.

17. The system of claim 16, wherein said transmission source emits triangular shaped waves, and wherein a start code and end code is embedded in said waves, such that plurality of sensors differentiate between said plurality of transmission sources.

18. The system of claim 1, wherein said transmission source emits triangular shaped waves, and wherein binary data is embedded in said waves, according to frequency modulation, voltage modulation or a combination thereof.
